(19) United States
(12) Patent Application Publication
(10) Pub. No.: US 2023/0290952 A1
(43) Pub. Date: Sep. 14, 2023

(54) OVERCOMING CYCLING LIMITATIONS FOR HIGH-ENERGY-DENSITY LITHIUM-ION BATTERIES

(71) Applicant: LAWRENCE LIVERMORE NATIONAL SECURITY, LLC, Livermore, CA (US)

(72) Inventors: Kathleen E. Vanderburgh, San Mateo, CA (US); Francesco Fornasiero, Oakland, CA (US); Jianchao Ye, Tracy, CA (US)

(21) Appl. No.: 17/694,030

(22) Filed: Mar. 14, 2022

(51) Int. Cl. H01M 4/62; H01M 4/1395; H01M 10/0525; H01M 4/66; H01M 4/04; C23C 16/06; H01M 4/38; C23C 16/26

(52) U.S. Cl. CPC H01M 4/625; H01M 4/1395; H01M 10/0525; H01M 4/661; H01M 4/0428; H01M 4/0404; C23C 16/06; H01M 4/663; H01M 4/382; C23C 16/26; H01M 2004/027

(57) ABSTRACT

Carbon nanotube (CNT) forests are grown directly on a base material for an anode. The CNTs are filled with Li metal. The filling behavior of the CNTs with Li metal is governed by the density, height, and diameter of the CNTs in the forest. These parameters are controlled by modifying the chemical vapor deposition (CVD) recipe used to grow the CNT forest along with adjusting the catalyst stack design to tune the aspect ratio, density, and rigidity of the CNT forest.

### STATEMENT AS TO RIGHTS TO APPLICATIONS MADE UNDER FEDERALLY SPONSORED RESEARCH AND DEVELOPMENT

This invention was made with Government support under Contract No. DE-AC52-07NA27344 awarded by the United States Department of Energy. The Government has certain rights in the invention.

### BACKGROUND

### Field of Endeavor

The present application relates to batteries and more particularly to lithium-ion batteries.

### State of Technology

This section provides background information related to the present disclosure which is not necessarily prior art.

Lithium metal is an ideal anode for high energy density LIBs due to its high theoretical capacity (3860 mAh/g), but is dangerous due to its propensity to form dendrites. Researchers have demonstrated dendrite-free lithium metal battery architectures, but the low charge efficiency of these electrodes (i.e., more Li+ ions are plated than stripped) impairs their durability and practical use as a higher energy density replacement for current LIBs. Studies have attempted to address the poor efficiency by improving the electrolyte with additives to enhance Li+ ion transportation, designing different current collector architectures to control Li deposition by manipulating Li+ flux and distribution, and even using a solid state electrolyte (SSE) to act as a physical barrier to stop dendrite growth from shorting the device, but have not been able to overcome the capacity fade of Li metal, resulting in battery failure after several cycles.

There is a serious need of mechanistic understanding of dendrite formation during commercial cell operations. Graphitic materials have been shown to be one of the most promising options for Li dendrite suppression as controlled diffusion interfaces, however the efficiency of current devices is lacking, and the conventional design prevents operation at higher currents without initiation of dendrite formation. Computational efforts as well as experimental studies have attempted to elucidate the role of graphitic interfaces in the stabilization of lithium metal anodes. However, these studies have isolated interfacial behavior using symmetrical cell architectures and have only paired their anode with positive battery material to measure performance, not to study dendrite formation. Consequently, there is lack of understanding of how dendrite formation nucleates during actual operations in full-cell architecture.

### SUMMARY

Features and advantages of the disclosed apparatus, systems, and methods will become apparent from the following description. Applicant is providing this description, which includes drawings and examples of specific embodiments, to give a broad representation of the apparatus, systems, and methods. Various changes and modifications within the spirit and scope of the application will become apparent to those skilled in the art from this description and by practice of the apparatus, systems, and methods. The scope of the apparatus, systems, and methods is not intended to be limited to the particular forms disclosed and the application covers all modifications, equivalents, and alternatives falling within the spirit and scope of the apparatus, systems, and methods as defined by the claims.

There are four basic components in a lithium-ion battery: anode, cathode, separator, and the electrolyte. Different chemistries can be used, for example; the anode can be graphite, the cathode can be a layered oxide (LiCoO₂), and the alternating layers of anode and cathode can be separated by a porous polymer separator made of polypropylene (PP), polyethylene (PE), or a laminate of PP and PE. The inventors' apparatus, systems, and methods provide for overcoming cycling limitations for high-energy-density lithium-ion batteries. Carbon nanotube (CNT) forests are grown directly on a base material for the anode. The CNTs are filled with Li metal. The filling behavior of the CNTs with Li metal is governed by the density, height, and diameter of the CNTs in the forest. These parameters are controlled by modifying the chemical vapor deposition (CVD) recipe used to grow the CNT forest along with adjusting the catalyst stack design to tune the aspect ratio, density, and rigidity of the CNT forest.

The inventors' Li-ion batteries apparatus, systems, and methods have use in consumer electronics and electric vehicles as well as other uses. The inventors' have developed technology that provides a route for a durable and safe battery with high energy density that would enable a mobile phone to last 5× as long without charging and would increase the free volume of the trunk of electric vehicles while drastically increasing the driving range 5-fold (750 Wh/kg, 1000 cycles).

The apparatus, systems, and methods are susceptible to modifications and alternative forms. Specific embodiments are shown by way of example. It is to be understood that the apparatus, systems, and methods are not limited to the particular forms disclosed. The apparatus, systems, and methods cover all modifications, equivalents, and alternatives falling within the spirit and scope of the application as defined by the claims.

### BRIEF DESCRIPTION OF THE DRAWINGS

The accompanying drawings, which are incorporated into and constitute a part of the specification, illustrate specific embodiments of the apparatus, systems, and methods and, together with the general description given above, and the detailed description of the specific embodiments, serve to explain the principles of the apparatus, systems, and methods.

FIG. 1 is a flow chart illustrating one embodiment of the inventors' apparatus, systems, and methods.

FIG. 2A is an illustrative cut away view one embodiment of a lithium-ion battery.

FIG. 2B is an illustrative cut away view one embodiment of a lithium-ion battery.

FIG. 3 is an illustrative view of a base material for an anode of a lithium-ion battery.

### DETAILED DESCRIPTION OF SPECIFIC EMBODIMENTS

Referring to the drawings, to the following detailed description, and to incorporated materials, detailed information about the apparatus, systems, and methods is provided including the description of specific embodiments. The detailed description serves to explain the principles of the apparatus, systems, and methods. The apparatus, systems, and methods are susceptible to modifications and alternative forms. The application is not limited to the particular forms disclosed. The application covers all modifications, equivalents, and alternatives falling within the spirit and scope of the apparatus, systems, and methods as defined by the claims.

Lithium-ion batteries (LIBs) lead as one of the most promising clean energy alternatives to power handheld electronics and grid size solutions. Lithium metal can supply the energy density needed for future technologies but poses serious safety risks due to the formation of dendritic metallic lithium that leads to cell failure. To overcome these risks, there is a need of anode architectures designed to combat the mechanisms of dendrite formation in a battery environment. The inventors' apparatus, systems, and methods provide a platform for controlled dendrite formation and better understand of capacity fade in LIBs, with the result of realizing safe energy storage technologies and increased energy density.

The inventors' apparatus, systems, and methods provide for overcoming cycling limitations of high-energy-density lithium-ion batteries. In one embodiment carbon nanotube (CNT) forests are grown directly on an anode base material of a lithium-ion battery (LIB). The CNTs are filled with Li metal. The filling behavior of the CNTs with Li metal is governed by the density, height, and diameter of the CNTs in the forest. These parameters are controlled by modifying the chemical vapor deposition (CVD) used to grow the CNT forest along with adjusting the catalyst stack design to tune the aspect ratio, density, and rigidity of the CNT forest.

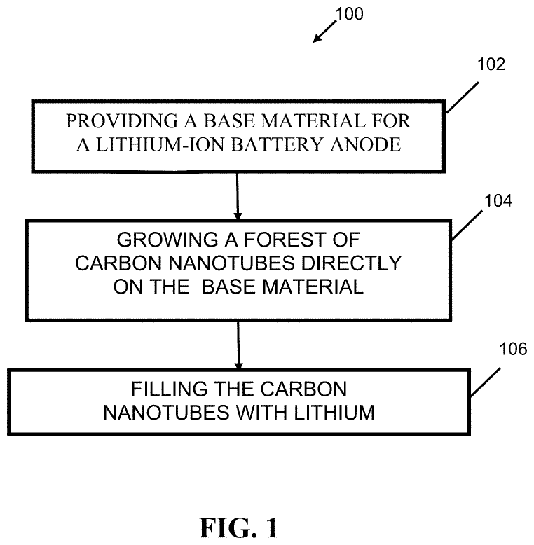

Referring now to the drawings and in particular to FIG. 1, a flow chart 100 illustrates one embodiment of the inventors' apparatus, systems, and methods. The flow chart 100 includes a number of steps. The steps of the inventor's apparatus, systems, and methods 100 illustrated in FIG. 1 are identified and described below.
Reference Numeral 102—providing a base material for a lithium-ion battery anode,
Reference Numeral 104—growing a forest of carbon nanotubes directly on the base material, and
Reference Numeral 106—filling the carbon nanotubes with lithium.

The description of the steps of one embodiment 100 of the inventors' apparatus, systems, and methods having been completed, additional details of the inventors' apparatus, systems, and methods 100 will now be considered. FIG. 1 illustrates a method of making an anode for a lithium-ion battery including the steps of providing a base material for the anode, growing a forest of carbon nanotubes directly on the base material, and filling the carbon nanotubes with lithium. The base material for the anode can be the anode itself or it can be a separate component connected to an anode component. The base material can be a metal foil base material, a copper foil base material, an Inconel metal base material, or other materials including copper, stainless steel, aluminum, Nickel, various Inconel alloys, graphite foil, graphene, etc.

In one embodiment 100 of the inventors' apparatus, systems, and methods of making an anode for a lithium-ion battery, the step of growing a forest of carbon nanotubes directly on the base material includes growing a forest of single wall carbon nanotubes directly on the base material. In another embodiment 100 of the inventors' apparatus, systems, and methods of making an anode for a lithium-ion battery, the step of growing a forest of carbon nanotubes directly on the base material includes aligning the carbon nanotubes on the base material.

In one embodiment 100 of the inventors' apparatus, systems, and methods of making an anode for a lithium-ion battery, the step of growing a forest of carbon nanotubes directly on the base material utilizes chemical vapor deposition to grow the forest of carbon nanotubes.

One embodiment 100 of the inventors' apparatus, systems, and methods includes the step of modifying the chemical vapor deposition to control carbon nanotube density, carbon nanotube height, and carbon nanotube diameter. Another embodiment 100 of the inventors' apparatus, systems, and methods includes the step of modifying the chemical vapor deposition to adjust aspect ratio, density, and rigidity of the carbon nanotube forest.

In one embodiment 100 the carbon nanotubes are filled with lithium metal. One embodiment 100 uses capillary filling for filling the carbon nanotubes with lithium. Another embodiment 100 uses electrochemical methods for filling the carbon nanotubes with lithium.

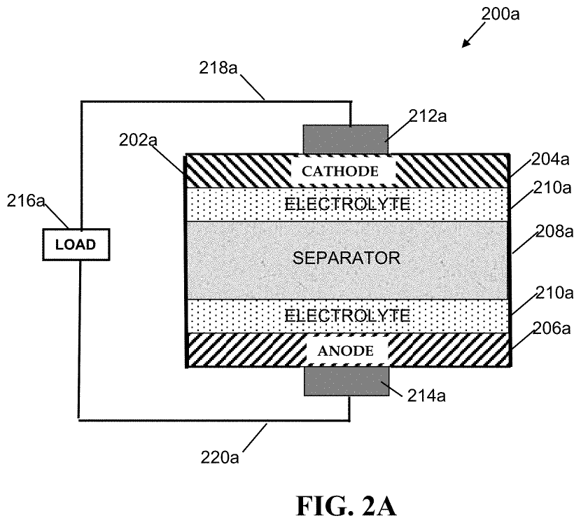

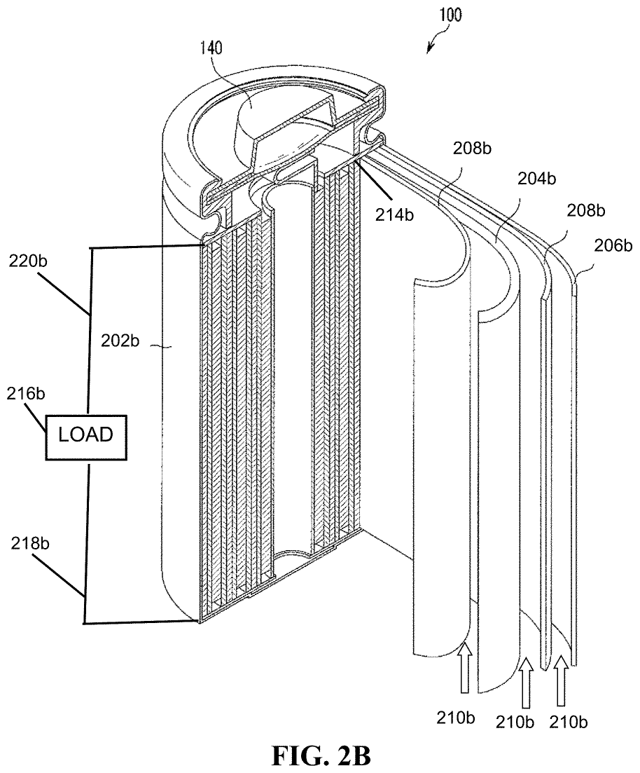

Referring to FIG. 2A, an illustrative view shows an embodiment of Applicants' apparatus, systems, and methods. This embodiment is identified generally by the reference numeral 200. FIG. 2A is an illustrative cut away view one embodiment of a lithium-ion battery 200a. The components of lithium-ion battery 200a in FIG. 2A are listed below.
Reference Number—202a Casing,
Reference Number—204a cathode,
Reference Number—206a anode,
Reference Number—208a separator,
Reference Number—210a electrolyte,
Reference Number—212a cathode terminal,
Reference Number—214a anode terminal,
Reference Number—216a load,
Reference Number—218a cathode connector 118, and
Reference Number—220a anode connector.

The description of the structural components of the example embodiment 200a of the inventors' apparatus, systems, and methods having been completed, the operation and additional description of the inventors' apparatus, systems, and methods 200a will now be considered in greater detail. As illustrated in FIG. 2A a battery casing 202a contains an anode 206a, a cathode 204a, an electrolyte 210a, and a separator 208a. The electrolyte 210a enables ion transport between cathode and anode. The separator 208a separates the anode area and the cathode area of the battery casing 202a. An anode terminal 214a and a cathode terminal 212a are connected to the anode and cathode respectively. An anode connector 220a and a cathode connector 218a provide an electrical circuit for load 216a.

Additional details of the anode 206a will now be considered. The additional details are not in the illustration 200a. The additional details of the anode 206a include a forest of vertical aligned (CNTs) on the anode 206a. The (CNTs) are grown directly on the anode 206a. The CNTs are filled with Li metal. The filling behavior of the CNTs with Li metal is governed by the density, height, and diameter of the CNTs in the forest. These parameters are controlled by adjusting the chemical vapor deposition recipe (CVD) used to grow the CNT forest. These parameters are also controlled by adjusting the catalyst stack design to tune the aspect ratio, density, and rigidity of the CNT forest.

Referring to FIG. 2B, an illustrative view shows another embodiment of Applicants' apparatus, systems, and methods. This embodiment is identified generally by the reference numeral 200b. A lithium-ion battery is disclosed and illustrated in U.S. Pat. No. 8,349,499 which in incorporated herein by this reference. FIG. 2B is an illustrative cut away view another embodiment of a lithium-ion battery 200b. The components of lithium-ion battery 200b in FIG. 2B are listed below.
Reference Number—202b Casing,
Reference Number—204b cathode,
Reference Number—206b anode,
Reference Number—208b separator,
Reference Number—210b electrolyte,
Reference Number—212b cathode terminal,
Reference Number—214b anode terminal,
Reference Number—216b load,
Reference Number—218b cathode connector, and
Reference Number—220b anode connector.

The description of the structural components of the example embodiment 200b of the inventors the inventors' apparatus, systems, and methods having been completed, the operation and additional description of the inventors' apparatus, systems, and methods 200b will now be considered in greater detail. As illustrated in FIG. 2B a battery casing 202b contains an anode 206b, a cathode 204b, an electrolyte 210b, and a separator 208b. The separator 208b separates the anode area and the cathode area of the battery casing 202b. An anode terminal 214b and a cathode terminal 212b are connected to the anode and cathode respectively. An anode connector 220b and a cathode connector 218b provide an electrical circuit for load 216b.

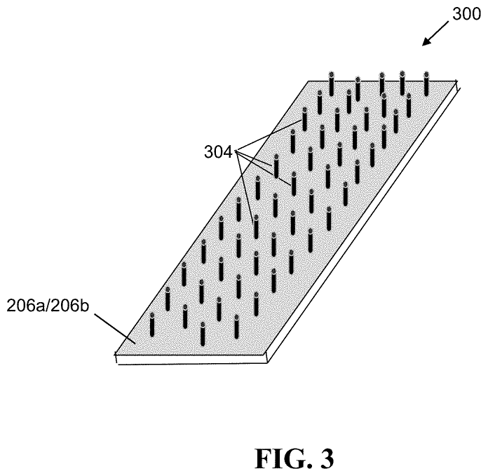

Additional details of the anode 206a will now be considered. The additional details are not in the illustration 200a. The additional details of the anode 206a include a forest of vertical aligned (CNTs) as the anode 206a. The (CNTs) are grown directly on the current collector 206a. The CNTs are the same as the CNTS 304 illustrated in FIG. 3. When grown the CNTs become the anode. The CNTs are filled with Li metal. The filling behavior of the CNTs with Li metal is governed by the density, height, and diameter of the CNTs in the forest. These parameters are controlled by adjusting the chemical vapor deposition recipe (CVD) used to grow the CNT forest. These parameters are also controlled by adjusting the catalyst stack design to tune the aspect ratio, density, and rigidity of the CNT forest.

Referring to FIG. 3, an illustrative view shows an embodiment of a base material for an anode for a lithium-ion battery. This embodiment is identified generally by the reference numeral 300. The components of the base material for an anode for a lithium-ion battery in FIG. 3 are listed below.
Reference Number—206a/206b base material for an anode for a lithium-ion battery, and
Reference Number—304 carbon nanotubes.

The description of the structural components of the embodiment 300 of the inventors' apparatus, systems, and methods having been completed, the operation and additional description of the embodiment 300 will now be considered in greater detail. As illustrated in FIG. 3 a forest of vertical aligned (CNTs) 304 are located on the base material anode 206a. The (CNTs) are grown directly on the base material 206a/206b of the anode. The base material 206a/206b can be the anode itself or it can be a separate component connected to an anode component. The base material can be a metal foil base material, a copper foil base material, an Inconel metal base material, graphene, or other materials.

The CNTs are filled with Li metal. The filling behavior of the CNTs with Li metal is governed by the density, height, and diameter of the CNTs in the forest. These parameters are controlled by adjusting the chemical vapor deposition (CVD) used to grow the CNT forest. These parameters are also controlled by adjusting the catalyst stack design to tune the aspect ratio, density, and rigidity of the CNT forest.

The present invention is further illustrated and described by a number of examples of systems constructed in accordance with the present invention. Various changes and modifications of these examples will be apparent to those skilled in the art from the description of the examples and by practice of the invention. The scope of the invention is not intended to be limited to the particular examples disclosed and the invention covers all modifications, equivalents, and alternatives falling within the spirit and scope of the invention as defined by the claims.

### Example 1

Fabrication of CNT Forest on Inconel Foil Filled with Li Metal

The inventors' apparatus, systems, and methods provide the growing of CNT forests directly on Inconel foil. Parameters such as density, height, and diameter of the CNTs in the forest are controlled by modifying the chemical vapor deposition (CVD) recipe used to grow the CNT forest along with adjusting the catalyst stack design to tune the aspect ratio, density, and rigidity of the CNT forest. These CNT forests are then characterized by Raman spectroscopy, SEM, and TEM. Then, this VASWCNT serves as a platform for fundamental understanding of dendrite formation in a full-cell configuration. The VASWCNT anode on Inconel foil was paired with Li metal in a half-cell configuration or with a layered oxide cathode material to study the effects of dendrite formation on cycle lifetime and degradation. These measurements were performed using cyclic voltammetry, galvanostatic cycling both in-operando and standard cycling with pre and post cycling characterization.

Full-cell architectures using the Li-filled CNT forest as the anode is assembled into 2032 coin cells paired with cell components typically employed in commercial LIBs. This configuration is better suited to understand dendrite growth and cell failure in application relevant conditions. Specifically, commercial lithium nickel manganese cobalt oxide (NMC) is used as the cathode, a 2525 Celgard polypropylene separator, and 1 M LiPF6 ethylene carbonate:diethyl carbonate (EC:DC) electrolyte. NMC is chosen as the cathode due to its high theoretical capacity of 278 mAh/g (>40% than most other cathodes) and high operating voltage of 3.0-4.2 V and is becoming the dominant cathode system in commercial cells. 1 M LiPF6 EC:DC is chosen as the electrolyte so that dendrite formation and capacity fade can be studied in an environment that mimics commercial batteries.

While previous work has simply looked at how the Li in the anode behaves upon dendrite formation, the inventors have investigated the intercalation behavior both at the cathode and anode, and how both sides contribute to cell demise through dendrite formation and capacity fade in application-relevant cell configuration and conditions. First, to demonstrate the capability of Li+ ions to plate and strip in the CNT, constant-current electrochemical measurements is performed over the specified operating voltage using a BioLogic potentiostat and galvanostat. The inventors have analyzed how the full-cell battery performance changes upon dendrite nucleation and growth with simultaneous electrochemical impedance spectroscopy (EIS) and Raman spectroscopy analysis. EIS enables characterization of the interfacial properties of the Li metal with the CNTs and to identify changes in resistance when dendrite formation begins. Raman spectroscopy is utilized in situ with electrochemical measurements to examine the vibrational modes of the bonding in the cathode and anode at different states of charge. This approach sheds light on the energy state of both anode and when dendrite formation is initiated and the subsequent cell failure.

### Example 2

Large-scale production of vertically aligned single-walled carbon nanotubes (VA-SWCNTs) enables technological advancements in many fields, from functional composites to energy storage. Synthesis of VACNTs on metal foils not only introduces an economical path towards mass production, but also paves the way for easy integration into thermal and electronic applications. In this work, the inventors demonstrated growth of high-quality vertically aligned SWCNTs on Inconel metal for use as a lithium-ion battery (LIB) anode. CNT growth on several Inconel alloy types (Inconel 600, 625, 718, 750) yields well-graphitized (G/D>6) VA-SWCNTs with average diameters ˜2-3 nm and very high densities surpassing 10¹² cm⁻². Scale-up of SWCNT growth on Inconel 625 up to 100 cm² exhibits nearly invariant CNT structural properties, even when synthesis is performed near atmospheric pressure, and this robustness is attributed to a growth kinetic regime dominated by the carbon precursor diffusion in the bulk gas mixture. Forests produced at conditions favorable for continuous processing (large area metal substrates and close to atmospheric pressure) possess among the best combination of structural features demonstrated so far in the literature for VACNT grown on metal foils. Leveraging these synthetic achievements for energy storage application, the inventors demonstrated that thinning the alumina barrier layer supporting the catalyst stack results in reduced VACNT-metal foil contact resistance but unchanged CNT forest properties and half-cell electrochemical performance (vs. Li metal) up to rates as high as 5.0 C (with respect to graphite). Notably, extending the voltage window up to 3.0 V results in capacity >1200 mAh/g at 1.0 C with stable cycling over 250 cycles. Overall, this robust synthesis of high-quality VA-SWCNTs on metal foil presents a promising route towards mass production of high-performance CNT devices for a broad range of applications, from energy storage and thermal interfaces to advanced composites and membranes.

While the apparatus, systems, and methods may be susceptible to various modifications and alternative forms, specific embodiments have been shown by way of example in the drawings and have been described in detail herein. However, it should be understood that the application is not intended to be limited to the particular forms disclosed. Rather, the application is to cover all modifications, equivalents, and alternatives falling within the spirit and scope of the application as defined by the following appended claims.

1. A method of making an anode for a lithium-ion battery, comprising the steps of:
providing a base material for the anode,
growing a forest of carbon nanotubes directly on the base material,
and
filling said carbon nanotubes with lithium.

2. The method of making an anode for a lithium-ion battery of claim 1 wherein said base material comprises a current collector.

3. The method of making an anode for a lithium-ion battery of claim 1 wherein said step of providing a base material for the anode comprises providing a metal foil base material for the anode.

4. The method of making an anode for a lithium-ion battery of claim 1 wherein said step of providing a base material for the anode comprises providing a Inconel foil base material for the anode.

5. The method of making an anode for a lithium-ion battery of claim 1 wherein said step of providing a base material for the anode comprises providing an Inconel metal base material for the anode.

6. The method of making an anode for a lithium-ion battery of claim 1 wherein said step of providing a base material for the anode comprises providing a graphene base material for the anode.

7. The method of making an anode for a lithium-ion battery of claim 1 wherein said step of growing a forest of carbon nanotubes directly on the base material comprises growing a forest of single wall carbon nanotubes directly on said base material.

8. The method of making an anode for a lithium-ion battery of claim 1 further comprising the step of aligning said carbon nanotubes on said base material.

9. The method of making an anode for a lithium-ion battery of claim 1 wherein said step of filling said carbon nanotubes with lithium comprises using capillary filling for filling said carbon nanotubes with lithium.

10. The method of making an anode for a lithium-ion battery of claim 1 wherein said step of filling said carbon nanotubes with lithium comprises using chemical vapor deposition filling for filling said carbon nanotubes with lithium.

11. The method of making an anode for a lithium-ion battery of claim 1 wherein said step of growing a forest of carbon nanotubes directly on the base material utilizes chemical vapor deposition to grow said forest of carbon nanotubes.

12. The method of making an anode for a lithium-ion battery of claim 11 further comprising the step of modifying said chemical vapor deposition to control carbon nanotube density, carbon nanotube height, and carbon nanotube diameter.

13. The method of making an anode for a lithium-ion battery of claim 11 further comprising the step of modifying said chemical vapor deposition to adjust aspect ratio, density, and rigidity of said carbon nanotube forest.

14. A lithium-ion battery, comprising:
a cathode,
an anode, and
a forest of vertically aligned carbon nanotubes grown directly on said anode.

15. The lithium-ion battery of claim 14 wherein said forest of vertically aligned carbon nanotubes are filled with lithium.

16. The lithium-ion battery of claim 14 wherein the anode is a copper foil anode.

17. The lithium-ion battery of claim 14 wherein the anode is an Inconel metal anode.

18. The lithium-ion battery of claim 14 wherein the anode is a graphene anode.

19. An anode for a lithium-ion battery, comprising:
a cathode,
a current collector, and
a forest of vertically aligned carbon nanotubes grown directly on said current collector.

20. The anode for a lithium-ion battery of claim 19 wherein said forest of vertically aligned carbon nanotubes are filled with lithium.

21. The anode for a lithium-ion battery of claim 19 wherein said current collector is a copper foil current collector.

22. The anode for a lithium-ion battery of claim 19 wherein said current collector is an Inconel metal current collector.

23. The anode for a lithium-ion battery of claim 19 wherein said current collector is a graphene current collector.
